(19) United States
(12) Patent Application Publication
(10) Pub. No.: US 2009/0297706 A1
(43) Pub. Date: Dec. 3, 2009

(54) FILM FORMING SYSTEM AND METHOD FOR FORMING FILM

(76) Inventors: Jiro Senda, Kyoto (JP); Motohiro Oshima, Kyoto (JP); Kozo Ishida, Kyoto (JP); Koji Tominaga, Kyoto (JP)

Correspondence Address: SNELL & WILMER LLP (OC), 600 ANTON BOULEVARD, SUITE 1400, COSTA MESA, CA, 92626, US

(21) Appl. No.: 11/908,437

(22) PCT Filed: Mar. 10, 2006
(86) PCT No.: PCT/JP2006/304726

§ 371 Date: May 27, 2009

(30) Foreign Application Priority Data
Mar. 16, 2005 (JP) 2005-075835

(51) Int. Cl. C23C 16/44

(52) U.S. Cl. 427/248.1; 118/715

(57) ABSTRACT

An obstruct of this invention is to make it possible to form a metal-oxide film or a metal-nitride film having less oxygen deficit at a high deposition rate with improved repeatability and to downsize a film forming system as well.

The film forming system in accordance with this invention comprises a chamber 3 inside of which a substrate 2 is held and an injection valve 4 that directly injects the liquid precursor into the chamber 3, wherein the liquid precursor is a mixed solution composed of a metallic compound and a low boiling point organic compound, and a pressure in the chamber 3 is made to be both larger than a vapor pressure of the metallic compound prior to being mixed with the low boiling point organic compound and smaller than a vapor pressure of the mixed solution.

### FIELD OF THE ART

This invention relates to a film forming system and a method for forming a film, more specifically to a film forming system and a method for forming a film to form a metal oxide film or a metal nitride film.

### BACKGROUND ART

Generally, in case of vaporizing a liquid precursor in a process of a chemical vapor deposition method (CVD method), mainly a heated liquid precursor is vaporized and supplied under a reduced pressure so that a thin film is formed on a substrate as being an object to be processed.

Conventionally, in case of forming a tantalum pentoxide (Ta₂O₅) film by the use of a metal compound that is liquid at room temperature and whose vapor pressure is smaller than or equal to 1 Torr at 100 centigrade degree, for example, pentaethoxytantalum (Ta(OC₂H₅)₅), a film is formed by heating pentaethoxytantalum (Ta(OC₂H₅)₅) at about 110 centigrade degree and by heating a substrate at about 400 centigrade degree. In this case, the liquid precursor is required to be heated to be gasified and a precursor supplying pipe for supplying the gasified liquid precursor to a chamber also is required to be heated at a high temperature. If there is a part of the precursor supplying pipe whose temperature is lower than that of the heated liquid precursor, the gasified liquid precursor coagulates again and an amount of the liquid precursor to be supplied to the chamber changes. As a result, there is a problem that repeatability of film forming is aggravated.

In addition, since a container of the liquid precursor and the precursor supplying pipe from the container to the chamber have to be kept at a high temperature, whole of the system becomes large-scaled, thereby increasing a device cost and an energy cost.

Recently in order to solve these problems there is a method as shown in the patent document 1 wherein a raw material of pentaethoxytantalum (Ta(OC₂H₅)₅) is sent to an evaporator in a state of liquid, vaporized by the evaporator and then sent to a chamber.

With this method, however, the above-mentioned problem is not still solved completely because the precursor supplying pipe from the evaporator to the chamber has to be kept at a high temperature.

Then a method has been taken wherein an injection valve (injector) is arranged in an upper part of a chamber and the liquid precursor is directly supplied into the chamber, as shown in the patent document 2.

However, in case of supplying the liquid precursor into the chamber with this method, the liquid precursor has to be vaporized completely and the film has to be formed under a condition wherein a degree of vacuum is high, namely, smaller than or equal to about 0.02 Torr, resulting in oxygen deficit in the tantalum pentoxide (Ta₂O₅) film. This invites a problem that it is difficult to obtain a tantalum pentoxide (Ta₂O₅) film of high grade.

Patent document 1 Japan patent laid-open number 2004-197134
Patent document 2 Japan patent laid-open number 2004-197135

### DISCLOSURE OF THE INVENTION

### Problems to be Solved by the Invention

The present claimed invention intends to solve all of the problems and a main object of this invention is to make it possible to form a metal oxide film or a metal nitride film having less oxygen deficit at a high deposition rate with improved repeatability and to downsize a film forming system as well.

### Means to Solve the Problems

More specifically, a film forming system in accordance with this invention is a film forming system that forms a film by vaporizing a liquid precursor and then depositing the vaporized liquid precursor on a substrate, and comprises a chamber inside of which the substrate is held and an injection valve that directly injects the liquid precursor into the chamber, wherein the liquid precursor is a mixed solution composed of a metallic compound and a low boiling point organic compound, and a pressure in the chamber is made to be larger than a vapor pressure of the metallic compound prior to being mixed with the low boiling point organic compound and smaller than a vapor pressure of the mixed solution.

In accordance with this arrangement, since the vapor pressure of the liquid precursor containing a metal compound (metal source) devoted to film forming can be raised without raising a temperature by mixing the low boiling point organic compound into the metal compound, and the film can be formed in a state that the pressure in the chamber is kept in a lower degree of vacuum than a pressure of a conventional method, it is possible to restrain generation of oxygen vacancies in a metal oxide film or nitrogen vacancies in a metal nitride film, thereby to obtain the metal oxide film or the metal nitride film of high quality. Furthermore, since the liquid precursor is directly injected into the chamber, a film can be formed at a high deposition rate with good repeatability and the film forming system can be downsized with no heater required for heating the precursor supplying pipe.

As a concrete embodiment, it is preferable that the metallic compound (precursor) is an organic tantalum compound (precursor) or an organic niobium compound.

Furthermore, it is preferable that a vapor pressure of the organic tantalum compound or the organic niobium compound is smaller than or equal to 1 Torr at a temperature more than or equal to 100 degrees centigrade in an atmospheric pressure. In addition, it is preferable that the organic tantalum compound or the organic niobium compound is liquid even though a temperature is lower than or equal to 40 degrees centigrade in an atmospheric pressure.

In addition to the above, it is conceived that the organic tantalum compound or the organic niobium compound is an alcoxide compound, an amine compound, a β diketone complex, a phenyl compound or a 5 member ring compound.

Concretely, the organic tantalum compound can be represented by the organic tantalum compound shown in FIG. 4, and the organic niobium compound can be represented by the organic niobium compound shown in FIG. 5.

As the low boiling point organic compound, it is preferable that its vapor pressure in an atmospheric pressure is larger than or equal to 1 Torr even though a temperature is lower than or equal to 20 degrees centigrade.

Furthermore, it is preferable that the low boiling point organic compound is a compound that can be shown by C_{X}H_{2X+2} (5≦X≦7).

A method for forming a film in accordance with this invention is a method for forming a film by vaporizing a liquid precursor and then depositing the vaporized liquid precursor on a substrate, and is characterized by that a mixed solution as the liquid precursor composed of a metallic compound and a low boiling point organic compound is directly injected into a chamber inside of which the substrate is held, and a pressure in the chamber is made to be both larger than a vapor pressure of the metallic compound prior to being mixed with the low boiling point organic compound and smaller than a vapor pressure of the mixed solution.

### Effect of the Invention

In accordance with this invention, since the vapor pressure of the liquid precursor containing a metal compound devoted to film forming can be raised without raising a temperature by mixing the low boiling point organic compound into the metal compound, and the film can be formed in a state the pressure in the chamber is kept in a lower degree of vacuum than a pressure of a conventional method, it is possible to restrain generation of oxygen vacancies in a metal oxide film or nitrogen vacancies in a metal nitride film, thereby to obtain the metal oxide film or the metal nitride film of high quality. Furthermore, since the liquid precursor is directly injected into the chamber, a film can be formed at a high deposition rate with good repeatability and the film forming system can be downsized with no heater required for heating the precursor supplying pipe.

### BRIEF DESCRIPTION OF THE DRAWINGS

FIG. 1 is a configuration diagram of a film forming system in accordance with an embodiment of the present claimed invention.

FIG. 2 is a table showing a value of a vapor pressure in a two phase region of a mixed solution composed of pentaethoxytantalum (Ta(OC₂H₅)₅) and low boiling point organic compound.

FIG. 3 is a table showing a dielectric breakdown withstand pressure of a tantalum pentoxide (Ta₂O₅) film.

FIG. 4 is a table showing varieties of an organic tantalum compound.

FIG. 5 is a table showing varieties of an organic niobium compound.

FIG. 6 is a table showing a value of a vapor pressure in a two-phase area of a mixed solution composed of pentaethoxyniobium (Nb(OC₂H₅)₅) and low boiling point organic compound.

FIG. 7 is a table showing a dielectric breakdown withstand pressure of a niobium pentoxide (Nb₂O₅) film.

FIG. 8 is a general configuration view of a film forming system in accordance with another embodiment.

FIG. 9 is a general configuration view of a film forming system in accordance with further different embodiment.

### BEST MODES OF EMBODYING THE INVENTION

Next, an embodiment of this invention will be explained with reference to the accompanying drawings.

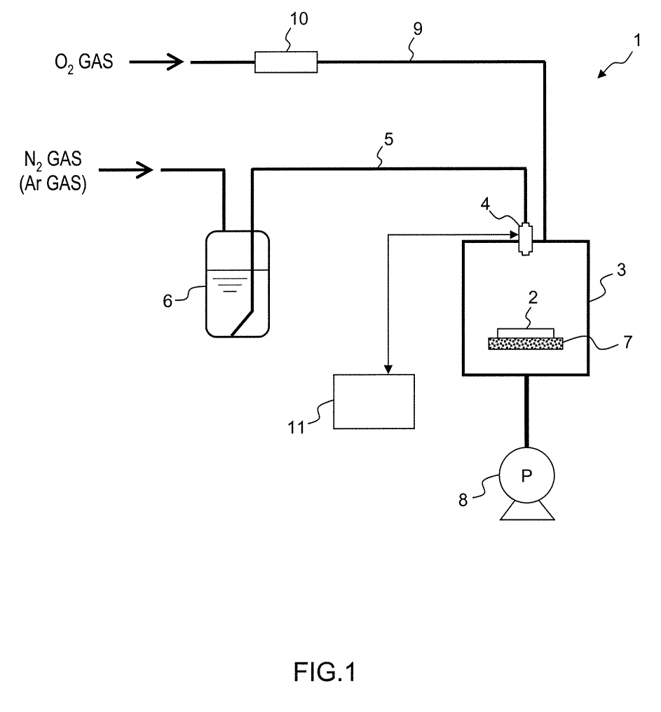

The film forming system 1 in accordance with this embodiment is, as shown in FIG. 1, a film forming system to form a film of tantalum pentoxide (Ta₂O₅) on a substrate 2 as being an object to be processed by vaporizing a liquid precursor and depositing a thin film on the substrate 2. A concrete main arrangement comprises a chamber 3 inside of which the substrate 2 is held, an injection valve 4 that directly injects the liquid precursor into the chamber 3 and a precursor supplying pipe 5 that supplies the injection valve 4 with the liquid precursor.

In this embodiment, a mixed solution of pentaethoxytantalum (Ta(OC₂H₅)₅) as being an organic compound and n-pentane (n-C₅H₁₂) as being low boiling point organic compound (solvent) is used as the liquid precursor. The mixed solution composed of pentaethoxytantalum (Ta(OC₂H₅)₅) and n-pentane (n-C₅H₁₂) is stored in a container 6 made of, for example, stainless-steel. And the mixed solution passes through a precursor supplying pipe 5 due to pressurized N₂ gas (Ar gas) pressed into the container 6 and then is supplied to the inside of the chamber 3 through an injection valve 4, to be described later. Furthermore, the liquid precursor is vaporized and filled in the chamber 3 at the same time when the liquid precursor is injected from the injection valve 4 into the inside of the chamber 3.

The chamber 3 internally holds the substrate 2 as being the object to be processed by means of a holding mechanism and further has a substrate heater 7 to heat the substrate 2. The chamber 3 is depressurized by a vacuum pump 8. In addition, an oxygen supplying pipe 9 to supply oxygen gas (O₂) for fully oxidizing a film of tantalum pentoxide (Ta₂O₅) is also arranged. A supplying flow amount of the oxygen (O₂) gas in the oxygen supplying pipe 9 is controlled by a mass flow controller (MFC) 10. Since the holding mechanism is a commonly used mechanism, a detailed explanation and a drawing will be omitted.

Furthermore, the pressure in the chamber 3 is adjusted so that pentaethoxytantalum (Ta(OC₂H₅)₅) in the mixed solution injected into the chamber 3 vaporizes. More specifically, the pressure in the chamber 3 is made to be both larger than a vapor pressure of pentaethoxytantalum (Ta(OC₂H₅)₅) prior to being mixed with n-pentane (n-C₅H₁₂) and smaller than a vapor pressure of the mixed solution composed of n-pentane (n-C₅H₁₂) and pentaethoxytantalum (Ta(OC₂H₅)₅).

The injection valve 4 directly injects the liquid precursor into the chamber 3 and is arranged in an upper part of the chamber 3 to face a surface of the substrate 2. The injection valve 4 is controlled to open or close by an injection valve controller 11 for controlling the injection valve 4 to open or close.

Next, an embodiment of thus arranged film forming system 1 is shown as follows.

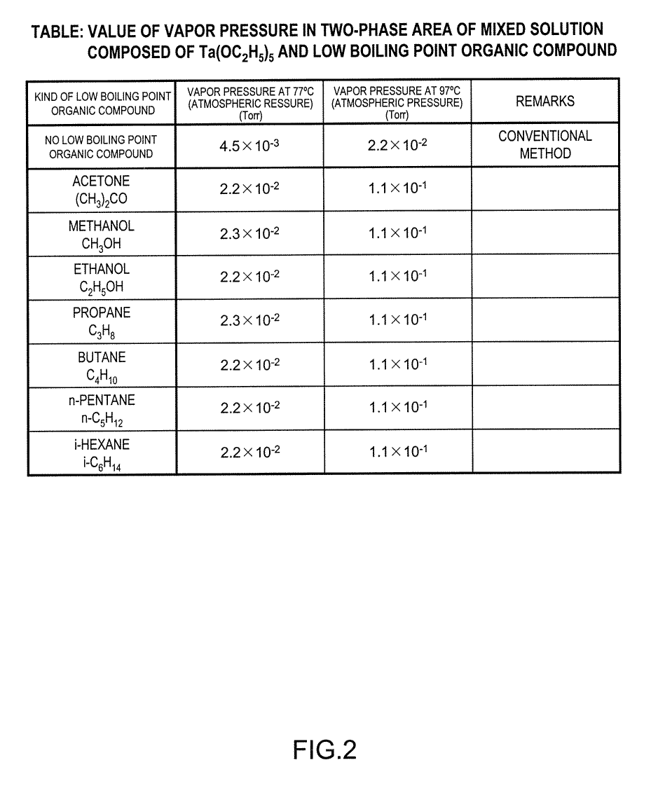

First, comparison results between the vapor pressure of the mixed solution composed of pentaethoxytantalum (Ta(OC₂H₅)₅) and acetone, methanol, ethanol, propane, butane, pentane and hexane as being the low boiling point organic compound and the vapor pressure of a pentaethoxytantalum (Ta(OC₂H₅)₅) solution without being mixed with the low boiling point organic compound is shown in FIG. 2. A mixing ratio is {(Ta(OC₂H₅)₅)/(Ta(OC₂H₅)₅+low boiling point organic compound)}=0.2 (mol ratio) by a mole fraction. From this result, it is turned out that if pentaethoxytantalum (Ta(OC₂H₅)₅) is mixed with the low boiling point organic compound, a two-phase area is formed and a vapor pressure of the mixed solution becomes about five times of a vapor pressure of the pentaethoxytantalum (Ta(OC₂H₅)₅) solution without being mixed with the low boiling point organic compound.

The mixing ratio of the liquid precursor in this embodiment is {(Ta(OC₂H₅)₅)/(Ta(OC₂H₅)₅)+n-C₅H₁₂}=0.2 (mol ratio). In addition, the pressure of the pressurized N₂ gas is made about 0.15˜0.50 MPa. The substrate heater 7 is set to make a temperature of the substrate 2 at 400 degrees centigrade ˜500 degrees centigrade, a flow rate of the oxygen gas is kept 500 ml/min and the pressure in the chamber 3 is set about 0.1 Torr. With this state kept, the injection valve 4 is open and closed so as to form a film for 1000 sec.

As a result of this, a thickness of a tantalum pentoxide (Ta₂O₅) film is about 150 nm. A film deposition rate is about 9 nm/min.

Next, electric characteristics of the formed tantalum pentoxide (Ta₂O₅) film is measured.

The silicon (Si) substrate is thermally oxidized so that a platinum (Pt) film of about 100 nm in thickness is formed on a silicon dioxide (SiO₂) film of about 200 nm in thickness, and then a tantalum pentoxide (Ta₂O₅) film is formed on the platinum (Pt) film.

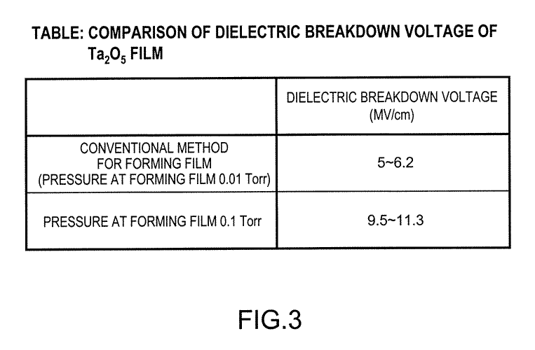

Later, a gold (Au) film of 0.5 m in thickness is formed by means of vacuum deposition and a dielectric breakdown electric field of tantalum pentoxide (Ta₂O₅) is obtained with the electrodes of platinum (Pt) and gold (Au). The results are shown in a table of FIG. 3. The comparison is made between the tantalum pentoxide (Ta₂O₅) film formed in the chamber 3 of a pressure of 0.01 Torr with a conventional film forming method and the tantalum pentoxide (Ta₂O₅) film formed in the chamber 3 of a pressure of 0.1 Torr with the firm forming method in accordance with this embodiment.

With the result shown in FIG. 2, a range of the pressure in the chamber 3 of this embodiment can be set between about 0.02˜0.1 Torr. More preferably, the pressure in the chamber 3 should be set to approach 0.1 Torr as much as possible.

Overall the dielectric breakdown withstand pressure of the tantalum pentoxide (Ta₂O₅) film formed with the conventional film forming method is small. This shows that a lot of defects exist in the tantalum pentoxide (Ta₂O₅) film, and the defects can be thought of as oxygen. In this case, it is necessary to decrease the oxygen defects by the use of an annealing treatment in the presence of oxygen after a conventional film forming.

In this embodiment, the partial pressure of oxygen can be increased ten times.

In accordance with thus arranged film forming system 1 of this embodiment, since the vapor pressure of the liquid precursor containing a metal compound devoted to film forming can be raised without raising a temperature by mixing the low boiling point organic compound into the metal compound, and the film can be formed in a state the pressure in the chamber 3 is kept in a lower degree of vacuum than that of a conventional method, it is possible to restrain generation of oxygen vacancies in a metal oxide film or nitrogen vacancies in a metal nitride film, thereby to obtain the metal oxide film or the metal nitride film of high quality. Furthermore, since the liquid precursor is directly injected into the chamber 3, a film can be formed at a high deposition rate with good repeatability and the film forming system 1 can be downsized with requiring no heater to heat the precursor supplying pipe 5. Accordingly, it is possible to make a device and a sensor by the use of various types of metal oxide films or metal nitride films, and especially they can be used as an insulating film for capacitors in a semiconductor element. In addition, since it is possible to obtain a film of high quality in as-depo, there is no need of a conventional post process (such as a process of heat treatment), thereby reducing manpower and contributing to a cost merit for equipment and an energy merit for environment.

The present claimed invention is not limited to the above-mentioned embodiments.

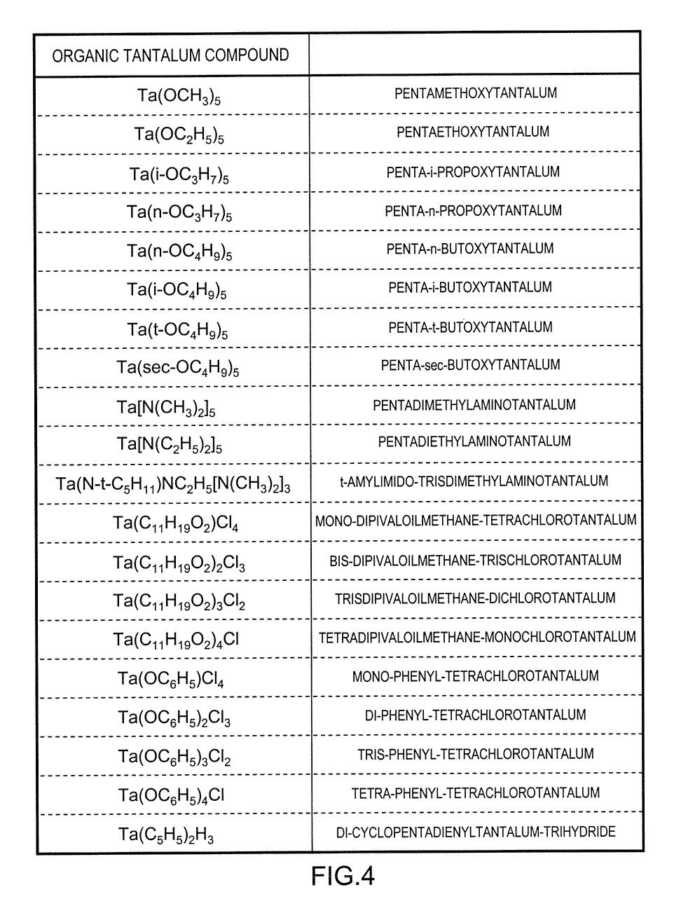

For example, in the above-mentioned embodiment, the film forming system 1 forms the tantalum pentoxide (Ta₂O₅) film by the use of pentaethoxytantalum (Ta(OC₂H₅)₅) as the organic tantalum compound (precursor) and n-pentane (n-C₅H₁₂) as the low boiling point organic compound, however, it is not limited to this and the tantalum pentoxide (Ta₂O₅) film may be formed by the use of organic tantalum compounds shown in FIG. 4.

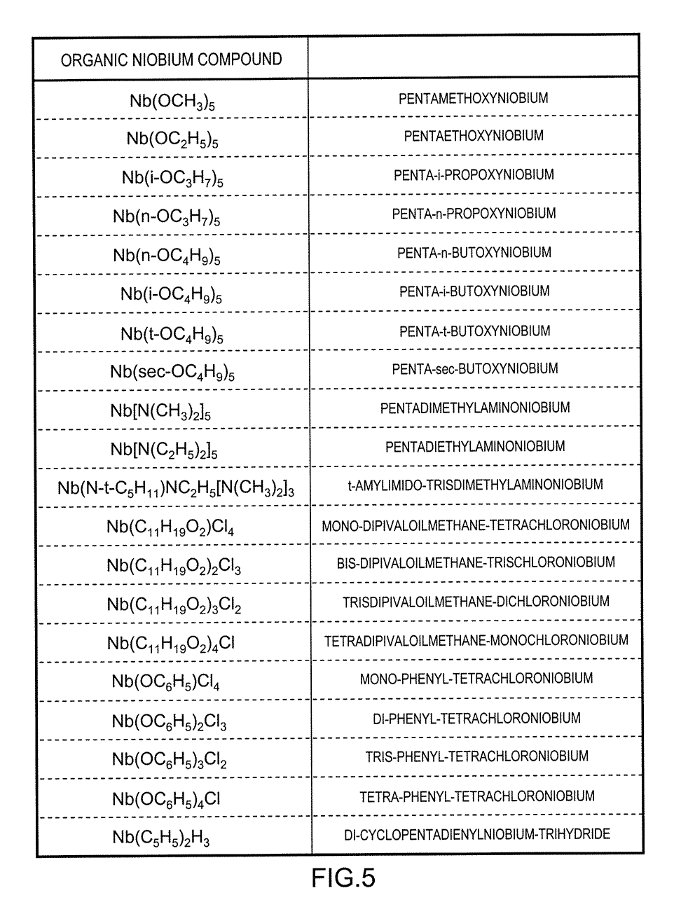

In addition, the film forming system 1 forms the tantalum pentoxide (Ta₂O₅) film, however, it may form a niobium pentoxide (Nb₂O₅) film. In this case, organic niobium compounds shown in FIG. 5 can be used as the organic niobium compound (precursor).

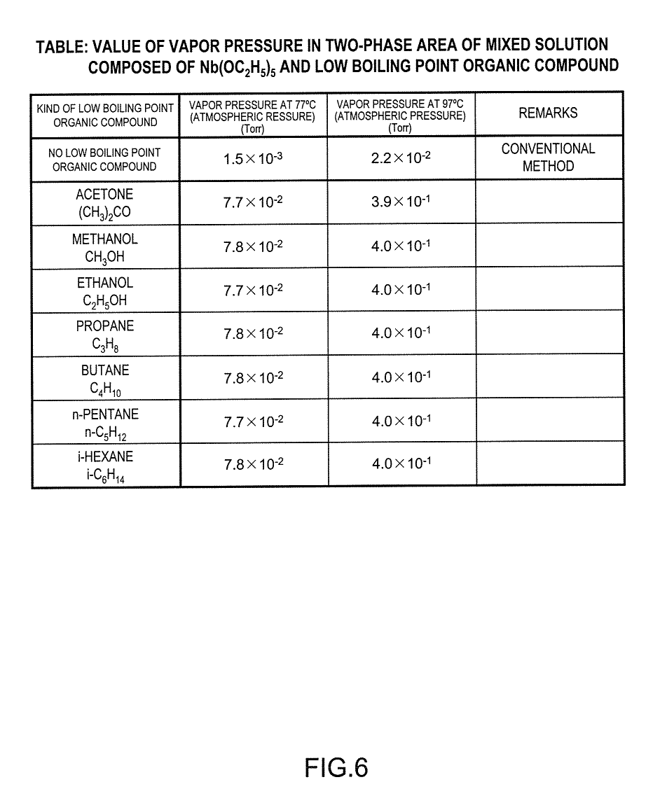

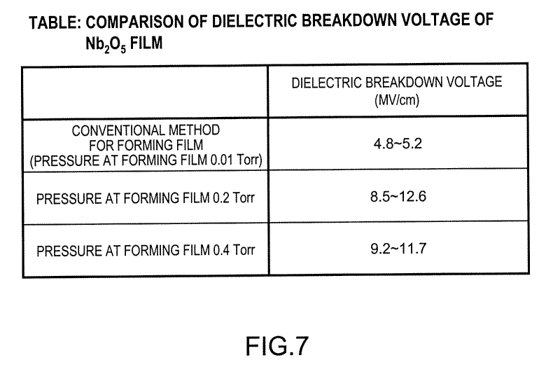

As this embodiment, comparison results between the vapor pressure of a mixed solution composed of pentaethoxyniobium (Nb(OC₂H₅)₅) and acetone, methanol, ethanol, propane, butane, pentane and hexane as being the low boiling point organic compound and the vapor pressure of a pentaethoxyniobium (Nb(OC₂H₅)₅) solution without mixing with the low boiling point organic compound is shown in FIG. 6. With the result shown in FIG. 6, a range of the pressure in the chamber 3 of this embodiment can be set between about 0.02˜0.4 Torr. More preferably, the pressure in the chamber 3 should be set to approach 0.4 Torr as much as possible. Furthermore, the dielectric breakdown withstand pressure of the niobium pentoxide (Nb₂O₅) film is shown in FIG. 7.

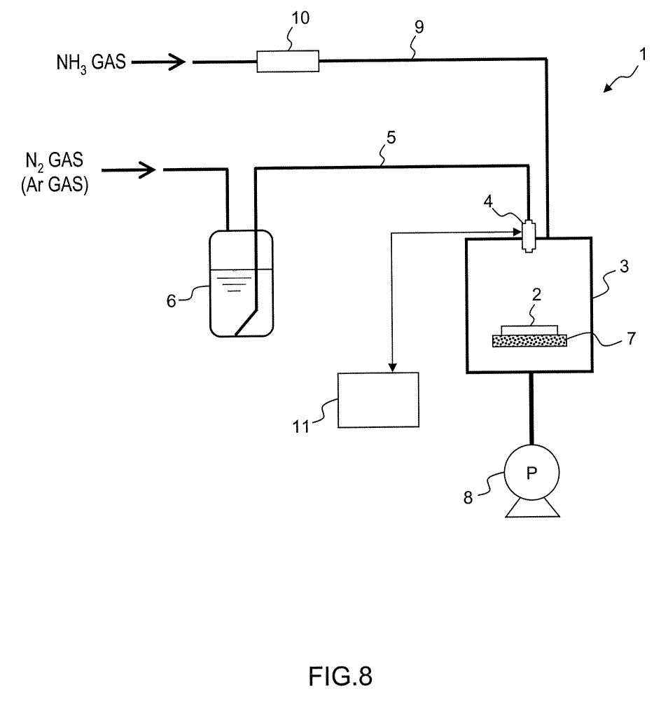

For the organic tantalum compound and the organic niobium compound whose constitutive element does not contain any oxygen atom, if ammonia gas is supplied, instead of oxygen, to the chamber, as shown in FIG. 8, a tantalum nitride (TaN) film or a niobium nitride (NbN) film can be formed.

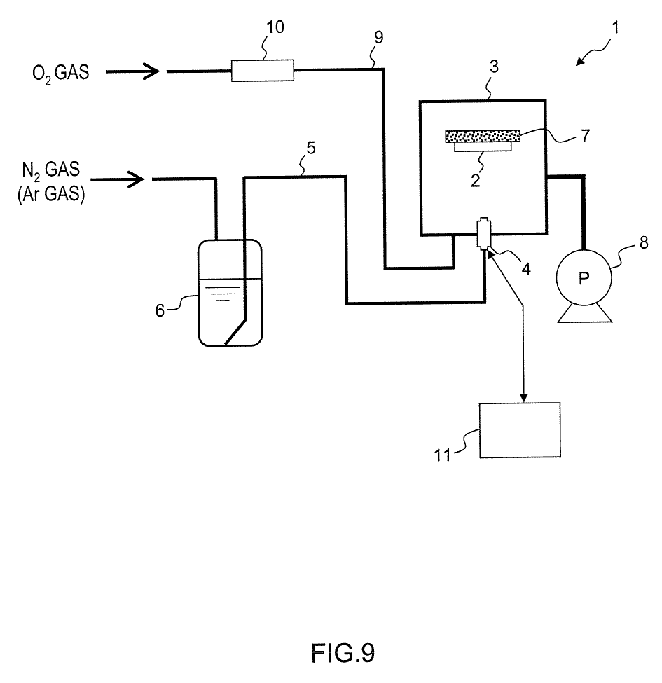

Furthermore, in the above-mentioned embodiment, the injection valve is arranged in an upper part of the chamber to face the substrate, however, the injection valve may be arranged in an lower part of the chamber to face the substrate as shown in FIG. 9. In addition, the injection valve may be arranged in a side face of the chamber to face the substrate.

The present claimed invention may be variously modified without departing from the spirit of the invention.

### POSSIBLE APPLICATIONS IN INDUSTRY

As mentioned, in accordance with the film forming system and the film forming method in accordance with this invention, since the vapor pressure of the liquid precursor containing a metal compound devoted to film forming can be raised without raising a temperature by mixing the low boiling point organic compound into the metal compound, and the film can be formed in a state the pressure in the chamber is kept in a lower degree of vacuum than a pressure of a conventional method, it is possible to restrain generation of oxygen vacancies in a metal oxide film or nitrogen vacancies in a metal nitride film, thereby to obtain the metal oxide film or the metal nitride film of high quality. Furthermore, since the liquid precursor is directly injected into the chamber, a film can be formed at a high deposition rate with good repeatability and the film forming system can be downsized with no heater required for heating the precursor supplying pipe.

1. A film forming system that forms a film by vaporizing a liquid precursor and then depositing the vaporized liquid precursor on a substrate, comprising
a chamber inside of which the substrate is held and an injection valve that directly injects the liquid precursor into the chamber, wherein
the liquid precursor is a mixed solution composed of a metallic compound and a low boiling point organic compound, and
a pressure in the chamber is made to be larger than a vapor pressure of the metallic compound prior to being mixed with the low boiling point organic compound and smaller than a vapor pressure of the mixed solution.

2. The film forming system described in claim 1, wherein
the metallic compound is an organic tantalum compound or an organic niobium compound.

3. The film forming system described in claim 2, wherein
a vapor pressure of the organic tantalum compound or the organic niobium compound is smaller than or equal to 1 Torr even though a temperature is more than or equal to 100 degrees centigrade in an atmospheric pressure.

4. The film forming system described in claim 2, wherein
the organic tantalum compound or the organic niobium compound is liquid at a temperature lower than or equal to 40 degrees centigrade in an atmospheric pressure.

5. The film forming system described in claim 2, wherein the organic tantalum compound or the organic niobium compound is an alcoxide compound, an amine compound, a β diketone complex, a phenyl compound or a 5 member ring compound.

6. The film forming system described in claim 1, wherein
a vapor pressure of the low boiling point organic compound in an atmospheric pressure is larger than or equal to 1 Torr even though a temperature is lower than or equal to 20 degrees centigrade.

7. The film forming system described in claim 1, wherein
the low boiling point organic compound is a compound that can be shown by C_{X}H_{2X+2} (5≦X≦7).

8. The film forming system described in claim 1, wherein the low boiling point organic compound is a compound that can be shown by C_{X}H_{2X+1}OH (1≦X≦4).

9. A film forming method for forming a film by vaporizing a liquid precursor and then depositing the vaporized liquid precursor on a substrate, wherein
a mixed solution as the liquid precursor composed of a metallic compound and a low boiling point organic compound is directly injected into a chamber inside of which the substrate is held, and a pressure in the chamber is made to be larger than a vapor pressure of the metallic compound prior to being mixed with the low boiling point organic compound and smaller than a vapor pressure of the mixed solution.

10. The film forming method for forming a film described in claim 9, wherein
the metallic compound is an organic tantalum compound or an organic niobium compound.
